(19) United States
(12) Patent Application Publication
(10) Pub. No.: US 2007/0257611 A1
(43) Pub. Date: Nov. 8, 2007

(54) DUAL-EMISSION ORGANIC ELECTROLUMINESCENT DEVICES

(75) Inventors: Min-Ling Hung, Pingtung County (TW); Chun-Yi Chiu, Taoyuan County (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU OPTRONICS CORP., Hsinchu (TW)

(21) Appl. No.: 11/466,810

(22) Filed: Aug. 24, 2006

(30) Foreign Application Priority Data
May 2, 2006 (TW) 95115603

(51) Int. Cl. H05B 33/04; H01J 1/62

(52) U.S. Cl. 313/512; 313/506

(57) ABSTRACT

A dual-emission organic electroluminescent device. The dual-emission organic electroluminescent device comprises a first imaging element and a second imaging element parallel the first imaging element, and a desiccant layer disposed between the first and second imaging elements within the inner space. The first and second imaging elements are encapsulated by an sealant, and an inner space is surrounded by the sealant. Specifically, the first imaging element has an emission direction opposite that of the second imaging element. Each of the first and second imaging elements comprises a substrate, an organic electroluminescent element formed on the substrate, and a buffer layer covering the organic electroluminescent element.

### CROSS-REFERENCE

This application claims the benefit of Taiwan Patent Application Serial No. 95115603, filed May 2, 2006, the subject matter of which is incorporated herein by reference.

### BACKGROUND OF THE INVENTION

1. Field of the Invention

The invention relates to an organic electroluminescent device, and more particularly to a dual-emission organic electroluminescent device.

2. Description of the Related Art

Liquid crystal displays (LCDs) generally perform well, but have somewhat narrow viewing angles, relatively slow response and require backlighting. Consequently, LCDs are not at their best for high-speed image animation and consume additional energy for backlighting. In addition, large LCDs are difficult to produce.

Organic light emitting diode (OLED) displays have been developed to address the disadvantages of LCDs. Unlike LCDs, which modulate light generated by backlighting systems, OLED displays emit light via an array of OLED-based pixels. Organic electroluminescent elements are self-emitting, and highly luminous, with wider viewing angle, faster response speed, and a simple fabrication process, making them the display of choice.

With the progress of information technology and the electronics, it is necessary not only to improve response time and resolution of the display but also to pursue the development of various functions and applications. For example, portable electronic products, which employ dual-emission display devices, such as mobile phones, PDAs, and notebooks, are strongly called for. Dual-emission display devices have advantages of extending screen space and simultaneously displaying various images. Accordingly, there has been increasing demand for organic electroluminescent devices which display images on both sides (dual-emission organic electroluminescent device).

However, most conventional dual-emission OLED displays, are assembled from two single-emission organic electroluminescent devices 11 and 12 to become a dual-screen display set 10, referring to FIG. 1. The organic electroluminescent devices 11 and 12 are individually packaged and then assembled back-to-back, comprising the dual-screen display set 10.

The dual-display devices described require individual packaging and then before being combined. Therefore, the size and the manufacture cost of the assembly are equal to that of two single-display devices. There is not any improvement in reducing the weight and the thickness of the assembly.

Therefore, it is necessary to develop a novel dual-emission organic electroluminescent device with thinner volume.

### BRIEF SUMMARY OF THE INVENTION

An exemplary embodiment a dual-emission organic electroluminescent device comprises a first imaging element and a second imaging element parallel to the first imaging element. A sealant is disposed between the first and second imaging elements to define an inner space therebetween. A desiccant disposed in the inner space. Specifically, the first imaging element has an emission direction opposite that of the second imaging element. Each of the first and second imaging elements comprises a substrate, an organic electroluminescent element formed on the substrate, and a buffer layer covering the organic electroluminescent element.

According to embodiments of the invention, the desiccant layer of the dual-emission organic electroluminescent device comprises metal or metal compound, such as calcium (Ca) or a Ca-containing compound.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a cross section of a conventional dual-screen display set.

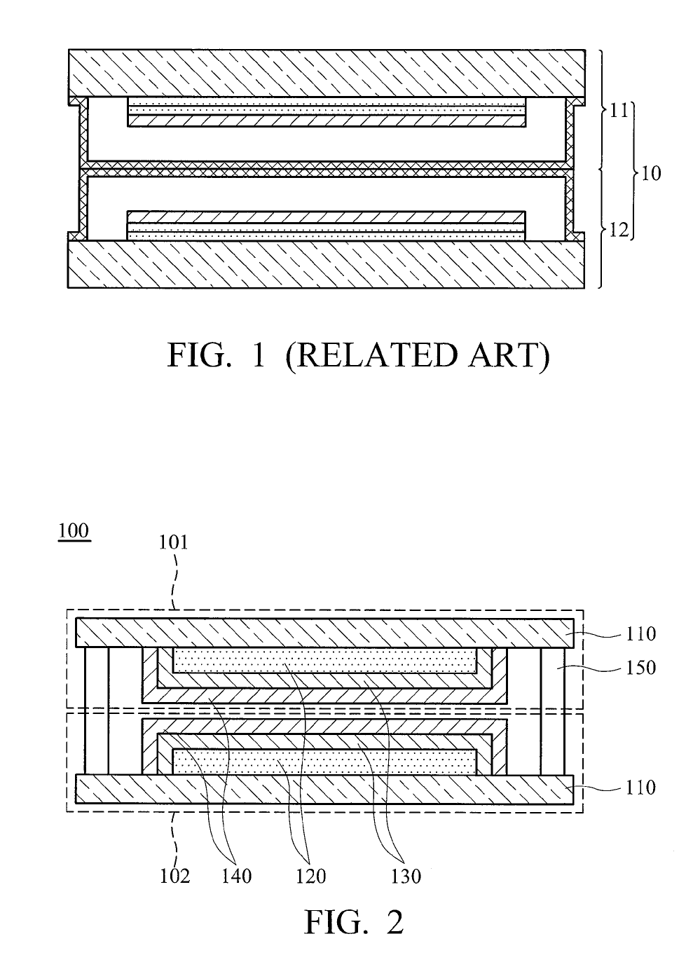

FIG. 2 is a cross section of dual-emission organic electroluminescent device according to an embodiment of the invention.

FIG. 3 is a top view of the dual-emission organic electroluminescent device according to FIG. 2.

FIGS. 4-7 are cross sections of dual-emission organic electroluminescent devices according to embodiments of the invention, illustrating the patterned desiccant layers.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

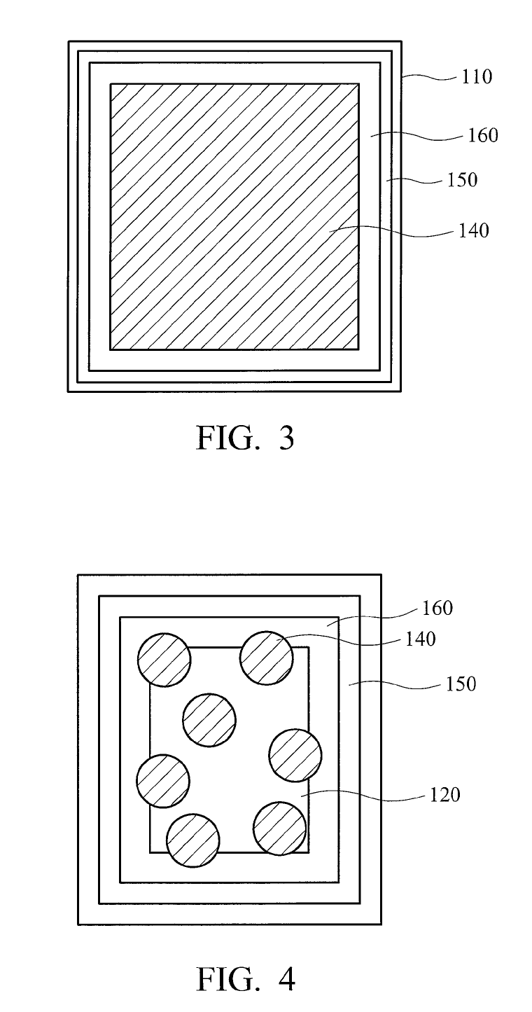

FIG. 2 is a cross section of a dual-emission organic electroluminescent device 100 according to an embodiment of the invention.

The dual-emission organic electroluminescent device 100 comprises a first imaging element 101 and a second imaging element 102, wherein the first imaging element 101 is bonded to the second imaging element 102 by means of a sealant 150. Further, the first imaging element 101 has an emission direction opposite to that of the second imaging element 102. Still referring to FIG. 2, each of the first and second imaging elements 101 and 102 comprises a substrate 110, an organic electroluminescent element 120 formed on the substrate 110, and a buffer layer 130 completely covering the organic electroluminescent element 120. Specifically, a desiccant layer 140 formed on the buffer layers 130 is disposed between the first and second imaging elements 101 and 102. The substrate 110 is made of glass, plastic, or ceramics.

The organic electroluminescent element 120 can be red, green, blue, or full color organic electroluminescent element, and comprises small molecule-based or polymer-based organic light emitting diodes. Further, the organic electroluminescent element 120 can comprise active matrix or passive matrix organic light emitting diode pixel arrays. The buffer layer 130 separates the organic electroluminescent element 120 from the desiccant layer 140. Suitable materials for the buffer layers 130 can be organic or dielectric material. It should be noted that the desiccant layer 140 comprises metal or metal compound and is formed on the buffer layer 130 by physical or chemical deposition. Further, the desiccant layer 140 can be formed in advance, and pasted on the buffer layers 130. Preferably, the desiccant layer 140 can comprise Ca or Ca-containing compound formed by deposition, sputtering, or CVD.

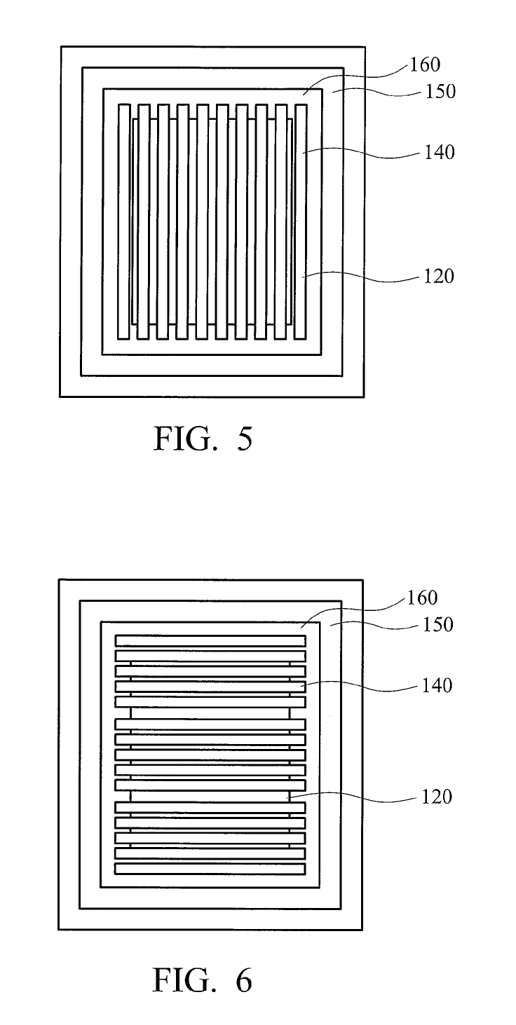

FIG. 3 is a top view of dual-emission organic electroluminescent device 100 according to FIG. 2, with first and second imaging elements 101 and 102 encapsulated by the sealant 150, and an inner region or space 160 surrounded by the sealant 150. Specifically, the desiccant layer 140 is formed within the inner region 160, and the sealant 150 does not contact or overlap with the desiccant layer 140. Conversely, if the desiccant layer 140 overlaps the predetermined region of the sealant 150, the sealant 150 contacts the desiccant layer 140, deteriorating the adhesive strength between the first and second imaging elements 101 and 102.

Furthermore, a desiccant layer 200 is formed on the light-emitting element 170 by PECVD of calcium, calcium oxide, or a combination thereof. In some embodiments of the invention, a protection layer can be optionally formed on the light-emitting element 170.

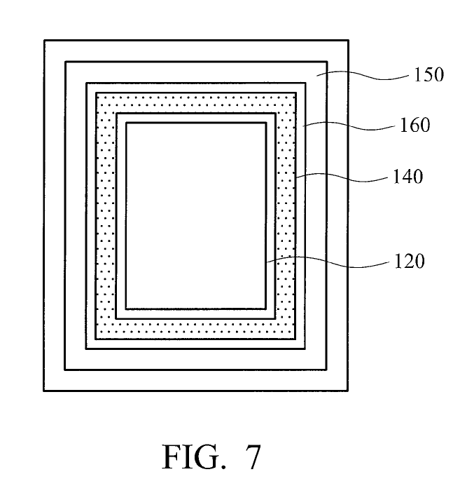

Referring to FIG. 3, the desiccant layer 140 can be a continuous layer in this embodiment. Further, referring to FIGS. 4˜7, the desiccant layer 140 can be a discrete patterned layer. In FIGS. 4˜5, in some embodiments, the desiccant layer 140 can have a pattern of stripes. In FIG. 6, the desiccant layer 140 can have a pattern of circles in another embodiment. Further, referring to FIG. 7, the substrate 110 has a projecting region according to the desiccant layer 140 surrounding the organic electroluminescent elements 120. Since the desiccant layer 140 according to the invention can be made of metal or metal compound, the pattern desiccant layer 140 can be formed by deposition, sputtering, or CVD with a shadow mask. In an embodiment of the invention, the sealant and the desiccant are non-overlapped.

Accordingly, the dual-emission organic electroluminescent devices of the invention have a thinner volume meeting the demands of the flat panel display market. Further, a ratio of an area of the desiccant to that of the inner space is between about 50% and about 100%. When the dimension ratio between the desiccant layer and the inner space is less than 50%, water and oxygen permeating from the atmosphere is completely adsorbed by the desiccant layer, extending reducing the performance and lifetime of the dual-emission organic electroluminescent devices. Conversely, adhesive strength between the first and second imaging elements 101 and 102 is reduced, when the dimension ratio between the desiccant layer and the inner region exceeds 100%.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A dual-emission organic electroluminescent device, comprising:
a first imaging element and a second imaging element parallel to the first imaging element, wherein the first imaging element has a emission direction opposite that of the second imaging element,
a sealant disposed between the first and second imaging elements to define an inner space therebetween; and
a desiccant disposed in the inner space, wherein each of the first and second imaging elements comprises:
a substrate;
an organic electroluminescent element formed on the substrate; and
a buffer layer covering the organic electroluminescent element.

2. The device as claimed in claim 1, wherein the substrate is made of glass, plastic, or ceramics.

3. The device as claimed in claim 1, wherein the desiccant layer is comprised of metal or a metal compound metal or a metal compound.

4. The device as claimed in claim 1, wherein the desiccant layer is comprised of calcium (Ca) or a Ca-containing compound.

5. The device as claimed in claim 1, wherein the desiccant layer is a continuous layer

6. The device as claimed in claim 1, wherein the desiccant layer is a discrete patterned layer.

7. The device as claimed in claim 6, wherein the desiccant layer has a pattern of stripes.

8. The device as claimed in claim 6, wherein the desiccant layer has a pattern of circles.

9. The device as claimed in claim 6, wherein the desiccant surrounds the organic electroluminescent element.

10. The device as claimed in claim 1, wherein the organic electroluminescent element comprises at least one small molecule-based organic light emitting diode.

11. The device as claimed in claim 1, wherein the organic electroluminescent element comprises at least one polymer-based organic light emitting diode.

12. The device as claimed in claim 1, wherein the organic electroluminescent element comprises an active matrix organic light emitting diode pixel array.

13. The device as claimed in claim 1, wherein the organic electroluminescent element comprises a passive matrix organic light emitting diode pixel arrays.

14. The device as claimed in claim 1, wherein the sealant is separated from the desiccant.

15. The device as claimed in claim 1, wherein a ratio of an area of the desiccant to that of the inner space is between about 50% and about 100%.

16. The device as claimed in claim 1, wherein the sealant and the desiccant are non-overlapped.
